(19) United States
(12) Patent Application Publication
(10) Pub. No.: US 2018/0240758 A1
(43) Pub. Date: Aug. 23, 2018

(54) SEMICONDUCTOR APPARATUS AND COMPOSITE SHEET

(71) Applicant: Lintec Corporation, Tokyo (JP)

(72) Inventors: NAOYA OKAMOTO, Tokyo (JP); TAIGA MATSUSHITA, Tokyo (JP); KAORI MATSUSHITA, Tokyo (JP)

(21) Appl. No.: 15/765,184

(22) PCT Filed: Oct. 7, 2016
(86) PCT No.: PCT/JP2016/079997

§ 371 Date: Mar. 30, 2018

(30) Foreign Application Priority Data
Oct. 13, 2015 (JP) 2015-202137

(51) Int. Cl. H01L 23/552; C09J 7/22; B32B 7/12; H01L 25/10; H01L 23/373; H01L 21/683

(52) U.S. Cl. CPC H01L 23/552; C09J 7/22; B32B 7/12; H01L 25/105; H01L 2221/68386; H01L 21/6836; B32B 2457/14; H01L 2225/1058; H01L 2221/68327; H01L 23/3733

(57) ABSTRACT

A semiconductor apparatus 100 according to an embodiment of the present invention includes a semiconductor substrate 11 and a protective layer 20. The semiconductor substrate 11 has a first surface constituting a circuit surface, and a second surface opposite to the first surface. The protective layer 20 includes a single layer of a composite material containing soft magnetic particles, and has an adhesive surface 201 to be adhered to the second surface.

### TECHNICAL FIELD

The present invention relates to a semiconductor apparatus and a composite sheet that include a protective film for semiconductor to be stuck to the back surface of a semiconductor device such as a semiconductor chip.

### BACKGROUND ART

In recent years, production of a semiconductor apparatus using a mounting method called a face-down method or a flip-chip connection is widely performed. In such a mounting method, the front surface (active surface) of a semiconductor chip, which constitutes a circuit surface, is disposed to face a wiring substrate, and a semiconductor chip is electrically and mechanically connected to the wiring substrate via a plurality of electrodes called bumps formed on the front surface.

To the back surface (non-active surface) of the semiconductor chip mounted by a face-down method, a protective film is often stuck in order to protect the semiconductor chip. As such a protective film, a film for flip-chip semiconductor back surface, which includes an adhesive layer and a protective layer that is laminated on this adhesive layer and formed of heat-resistant resin or metal, is known (see, for example, Patent Literature 1).

Meanwhile, with recent miniaturization and high functionality of electronic apparatuses, the influence of electromagnetic crosstalk between semiconductor chips on the wiring substrate becomes large. In order to solve such a problem, an adhesive film for semiconductor apparatus having a laminated structure of an adhesive layer and an electromagnetic wave shielding layer has been developed (see, for example, Patent Literature 2).

Patent Literature 1: Japanese Patent Application Laid-open No. 2012-33626

Patent Literature 2: Japanese Patent Application Laid-open No. 2012-124466

### SUMMARY OF INVENTION

### Problem to be Solved by the Invention

In recent years, demands for reducing the thickness of electronic apparatuses, and the thickness of the semiconductor apparatus to be incorporated into the electronic apparatus have been reduced. However, as described in Patent Literatures 1 and 2, since the film to be adhered to the back surface of the semiconductor chip includes two layers, there is a limit to reducing the thickness of the semiconductor apparatus. Such a problem becomes more significant in the case where the above-mentioned film is applied to individual semiconductor chips constituting the semiconductor apparatus having a stacked structure such as CoC (Chip on Chip) and PoP (Package on Package).

In view of the circumstances as described above, it is an object of the present invention to provide a semiconductor apparatus and a composite sheet that are capable of realizing the thickness reduction while having a function of protecting a semiconductor chip and a noise reduction function.

### Means for Solving the Problem

In order to achieve the above-mentioned object, a semiconductor apparatus according to an embodiment of the present invention includes a semiconductor substrate and a protective layer.

The semiconductor substrate has a first surface constituting a circuit surface, and a second surface opposite to the first surface.

The protective layer includes a single layer of a composite material containing soft magnetic particles, and has an adhesive surface to be adhered to the second surface.

In the semiconductor apparatus, the protective layer is integrated with the semiconductor substrate by bonding the adhesive surface to the back surface of the semiconductor substrate. Therefore, the protective layer that protects the back surface of the semiconductor substrate includes a single layer, so that it is possible to reduce the thicknesses of the protective layer and the semiconductor apparatus. Further, since the protective layer is formed of the composite material containing the soft magnetic particles, the bending strength of the semiconductor substrate can be enhanced, and electromagnetic noise emitted from the semiconductor substrate to the outside and electromagnetic noise entering the semiconductor substrate from the outside can be suppressed.

The composite material is typically formed of a cured product of thermosetting adhesive resin in which the soft magnetic particles are dispersed. Accordingly, it is possible to easily form a protective layer that has the strength necessary for protecting the back surface of the semiconductor substrate and an electromagnetic noise reduction effect, and includes a single layer.

The semiconductor substrate may be a semiconductor wafer or a semiconductor bare chip divided into chips having a chip size.

The protective layer may further contain thermally conductive particles. Accordingly, it is possible to obtain a protective layer that has not only an excellent electromagnetic noise absorption characteristic but also an excellent heat radiation characteristic of a semiconductor substrate.

A semiconductor apparatus according to another embodiment of the present invention includes a wiring substrate, a semiconductor device, and a protective layer.

The semiconductor device has a first surface constituting a circuit surface and a second surface opposite to the first surface, and is mounted on the wiring substrate.

The protective layer includes a single layer of a composite material containing soft magnetic particles, and has an adhesive surface to be adhered to the second surface.

The method of mounting the semiconductor device on the wiring substrate is not particularly limited, and flip-chip connection or wire bond connection may be used. In the case of flip-chip connection, the protective layer is disposed on the upper surface (surface opposite to the wiring substrate) of the semiconductor device. Meanwhile, in the case of wire bond connection, the protective layer is disposed as an adhesive layer between the semiconductor device and the wiring substrate.

The semiconductor apparatus may further include a semiconductor package component to be electrically connected to the wiring substrate. In this case, the semiconductor device is disposed between the wiring substrate and the semiconductor package component.

Further, since the protective layer includes a single layer, even in the case where the semiconductor apparatus has a stacked structure, it is possible to reduce the thickness of the semiconductor apparatus while suppressing electromagnetic crosstalk between the semiconductor device and the semiconductor package component.

A semiconductor apparatus according to still another embodiment of the present invention includes a first semiconductor device, a second semiconductor device, and an adhesive layer.

The second semiconductor device is disposed on the first semiconductor device, and electrically connected to the first semiconductor device.

The adhesive layer is formed of a nonconductive composite material containing soft magnetic particles, and disposed between the first semiconductor device and the second semiconductor device.

A composite sheet according to an embodiment of the present invention is bonded to a second surface opposite to a first surface constituting a circuit surface of a semiconductor substrate, and includes a protective layer and a support sheet.

The protective layer includes a single layer of a composite material containing soft magnetic particles, and has an adhesive surface to be adhered to the second surface.

The support sheet is peelably stuck to the front surface of the protective layer opposite to the adhesive surface.

The support sheet may include a dicing sheet for protecting and fixing the semiconductor substrate in a step of dicing the semiconductor substrate, and for picking up a semiconductor chip divided into chips having a chip size.

The protective layer may further contain a thermally conductive inorganic filler. Since the inorganic filler improves the thermal diffusivity of the protective layer, it is possible to effectively diffuse the heat generation of the semiconductor substrate.

The inorganic filler may contain anisotropically shaped particles having substantially the same long axis direction as the thickness direction of the protective layer. Since the anisotropically shaped particles exhibit a favorable thermal diffusivity in the long axis direction thereof, the heat generated in the semiconductor substrate is likely to diverge via the protective layer.

### Effects of the Invention

As described above, according to the present invention, it is possible to provide a semiconductor apparatus that is capable of realizing the thickness reduction while having a function of protecting a semiconductor chip and a noise reduction function.

### BRIEF DESCRIPTION OF DRAWINGS

FIG. 1 A schematic cross-sectional side view showing a configuration of a semiconductor apparatus according to a first embodiment of the present invention.

FIG. 2 A schematic cross-sectional side view showing a composite sheet including a protective layer in the semiconductor apparatus.

FIG. 3 A schematic process cross-sectional view describing a method of producing the semiconductor apparatus.

FIG. 4 A schematic plan view showing a pre-cut shape of the composite sheet.

FIG. 5 A schematic diagram describing an example of an adhering step of the composite sheet.

FIG. 6 A schematic diagram describing another example of the adhering step of the composite sheet.

FIG. 7 A schematic cross-sectional side view showing a configuration of a semiconductor apparatus according to a second embodiment of the present invention.

FIG. 8 A schematic cross-sectional side view showing a configuration of a semiconductor apparatus according to a third embodiment of the present invention.

FIG. 9 A schematic cross-sectional side view showing a configuration of a semiconductor apparatus according to a fourth embodiment of the present invention.

### MODES FOR CARRYING OUT THE INVENTION

Hereinafter, embodiments of the present invention will be described with reference to the drawings.

### First Embodiment

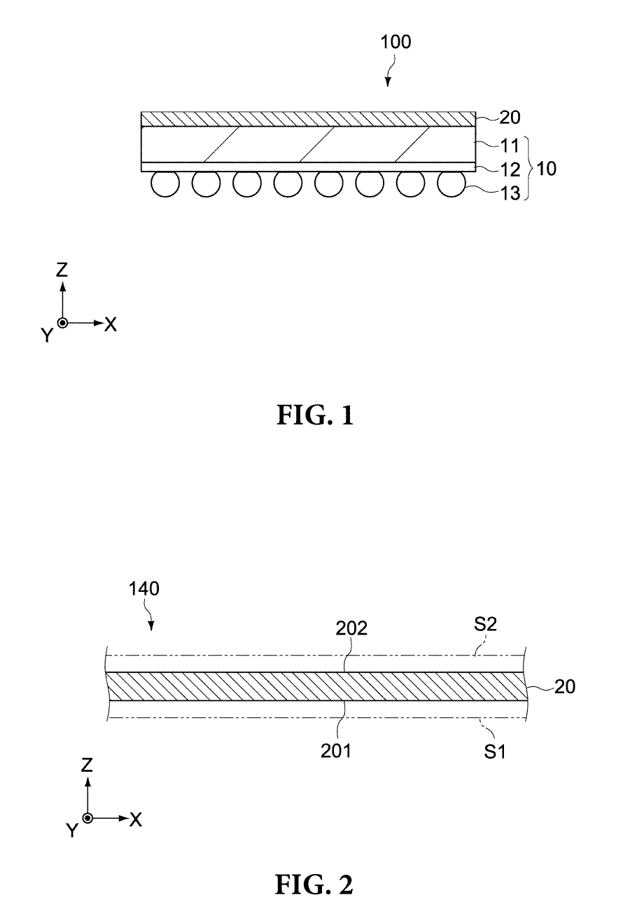

FIG. 1 is a schematic cross-sectional side view showing a configuration of a semiconductor apparatus 100 according to an embodiment of the present invention.

In the figure, the X axis, the Y axis, and Z axis represent three-axis directions perpendicular to each other, and the Z axis direction corresponds to the height direction (thickness direction) of the semiconductor apparatus 100.

As shown in FIG. 1, the semiconductor apparatus 100 according to this embodiment includes a semiconductor device 10 and a protective layer 20.

### Semiconductor Apparatus

The semiconductor apparatus 100 includes a chip size package (WLCSP) prepared at the wafer level. The semiconductor device 10 includes a semiconductor substrate 11, a wiring layer 12 formed on the front surface (first surface) of this semiconductor substrate 11, which constitutes a circuit surface, and a plurality of bumps 13 connected to the wiring layer 12.

The semiconductor substrate 11 includes a semiconductor wafer of single crystal silicon, silicon carbide, gallium nitride, gallium arsenide, or the like, or a semiconductor chip obtained by dividing (dicing) this into chips having a predetermined size. The thickness of the semiconductor substrate 11 is not particularly limited, and is, for example, 25 to 400 μm.

The wiring layer 12 is for connecting a plurality of electrodes formed on the circuit surface of the semiconductor substrate 10 to the plurality of bumps 13, and includes a wiring layer for rearranging the positions and pitches of the plurality of electrodes to predetermined positions and pitches, respectively. Each of the plurality of bumps 13 includes a bump electrode such as a solder bump and a gold bump.

Note that the semiconductor device 10 may include only the semiconductor substrate 11 (bare chip), or the wiring layer 12 may be omitted (the bumps 13 may be directly arranged on the electrodes of the semiconductor substrate 11).

### Protective Layer

The protective layer 20 constitutes a protective film for semiconductor to be provided on the back surface (second surface) of the semiconductor substrate 11. By being provided on the back surface of the semiconductor substrate 11, the protective layer 20 is configured to exhibit various functions such as improvement in the rigidity (bending strength) of the semiconductor substrate 11, protection of the back surface of the semiconductor substrate 11, display of the type of the semiconductor substrate 11, suppression of warpage of the semiconductor substrate 11, and absorption of electromagnetic noise emitted from the semiconductor substrate 11 and electromagnetic noise entering the semiconductor substrate.

FIG. 2 is a schematic cross-sectional side view showing the protective layer 20.

The protective layer 20 constitutes a composite sheet 140 together with a peeling sheet S1 and a support sheet S2. The protective layer 20 has an adhesive surface 201 to be adhered to the back surface of the semiconductor substrate 11 (semiconductor device 10), and is peelably covered with the peeling sheet S1 when not in use. A front surface 202 of the protective layer 20 opposite to the adhesive surface 201 is supported by the support sheet S2. The support sheet S2 is removed after the protective layer 20 is adhered to the semiconductor substrate 11.

As shown in FIG. 2, the protective layer 20 includes a single layer of a composite material containing soft magnetic particles. The thickness of the protective layer 20 is not particularly limited, and is within the range of, for example, not less than 20 μm and not more than 400 μm, preferably, not less than 25 μm and not more than 300 μm.

The composite material constituting the protective layer 20 is formed of a cured product of electrically insulating adhesive resin containing soft magnetic particles.

### Soft Magnetic Particles

The soft magnetic particles are not particularly limited as long as they are powders of magnetic materials having a soft magnetic characteristic, and powders of various magnetic materials such as alloy-based, oxide-based, and amorphous-based materials can be adopted.

As the alloy-based magnetic material, Sendust (Fe—Si—Al alloy) is typically used. Other examples of the alloy-based magnetic material include Permalloy (Fe—Ni alloy), silicon copper (Fe—Cu—Si alloy), and magnetic stainless steel. Typical examples of the oxide magnetic material include ferrite (Fe₂O₃). Typical examples of the amorphous-based magnetic material include a transition metal-metalloid-based amorphous material, more specifically, Fe—Si—B-based and Co—Fe—Si—B-based materials. The type of the magnetic material can be appropriately selected depending on the frequency characteristic of the target electromagnetic wave and the like for the purpose of electromagnetic wave absorption, and among them, the magnetic material having a high magnetic permeability characteristic such as Sendust is preferable because it is capable of covering a relatively wide frequency band.

The powder form of the soft magnetic particles is also not particularly limited, and those having a flat shape including a scaly shape and a flake shape in addition to those having a spherical shape or a needle shape are used. Among them, those having a flat shape are preferable. In particular, it is more preferable that these magnetic powders having a flat shape are oriented in parallel with the planar direction of the protective layer 20, and dispersed so that they overlap each other in the thickness direction of the protective layer 20 to form multiple layers.

In this case, the average particle size of the soft magnetic particles is arbitrarily set according to the flatness ratio or average thickness thereof, and is, for example, within the range of not less than 100 nm and not more than 100 μm. In the case where nano-ferrite particles are used as the soft magnetic particles, the lower limit of the particle size is 100 nm, preferably 1 μm. Note that the flatness ratio is calculated as the aspect ratio obtained by dividing the average particle size (average length) of the soft magnetic particles b the average thickness thereof. By adjusting the average particle size, flatness ratio, average thickness, and the like of the soft magnetic particles, it is possible to reduce the influence of the diamagnetic field by the soft magnetic particles, and improve the magnetic permeability of the soft magnetic particles.

Note that in this specification, the average particle size of soft magnetic particles is measured by a dry method using a cyclone injection-type dry measurement unit (SALD-DS5), with a laser diffraction-type particle size distribution measuring apparatus (SALD-2300) manufactured by Shimadzu Corporation as a measuring apparatus,

The content of the soft magnetic particles in the protective layer 20 are, for example, within the range of not less than 30% by mass and not more than 95% by mass, preferably not less than 40% by mass and not more than 90% by mass. In the case where the content of the soft magnetic particles is too small, sufficient electromagnetic noise suppression effect as the protective layer 20 cannot be achieved. Further, in the case where the content of the soft magnetic particles is too large, sufficient adhesion strength, holding strength of the soft magnetic particles, and the like as the protective layer 20 cannot be obtained.

### Resin Component

Meanwhile, the resin component of the adhesive resin includes at least one of a thermosetting component and an energy ray-curable component, and a binder polymer component.

Examples of the thermosetting component include epoxy resin, phenol resin, melamine resin, urea resin, polyester resin, urethane resin, acrylic resin, polyimide resin, benzoxazine resin, and mixtures thereof. In particular, in this embodiment, epoxy resin, phenol resin, and mixture thereof are preferably used.

Among them, in this embodiment, bisphenol-based glycidyl-type epoxy resin, o-cresol-novolak-type epoxy resin, and phenol-novolak-type epoxy resin are preferably used. These epoxy resins can be used alone or in combination of two or more.

The energy ray-curable component is formed of a compound that is polymerized and cured when irradiated with energy rays such as ultraviolet rays and electron rays. This compound has at least one polymerizable double bond in the molecule, and usually has a molecular weight of 100 to 30,000, preferably approximately 300 to 10,000. As such an energy ray polymerizable compound, trimethylolpropane triacrylate, tetramethylolmethane tetraacrylate, pentaerythritol triacrylate, dipentaerythritolmonohydroxypentaacrylate, and dipentaerythritol hexaacrylate, or 1, 4-butylene glycol diacrylate, 1, 6-hexanediol diacrylate, polyethylene glycol diacrylate, oligoester acrylate, further, polyester-type or polyether-type urethane acrylate oligomer, polyester acrylate, polyether acrylate, epoxy modified acrylate, and the like can be used.

Among them, in this embodiment, ultraviolet curable resin is preferably used, and specifically, oligoester acrylate, urethane acrylate oligomer and the like are particularly preferably used. By mixing a photopolymerization initiator into the energy ray-curable component, it is possible to reduce the polymerization curing time and the amount of light irradiation.

The binder polymer component is used for giving an appropriate tack to the protective layer 20, and improving the film formability and operability of the sheet. The weight average molecular weight of the binder polymer is usually within the range of 50,000 to 2,000,000, preferably 100,000 to 1,500,000, particularly preferably, 200,000 to 1,000,000. In the case where the molecular weight is too small, the sheet formation becomes insufficient. In the case where the molecular weight is too large, the flexibility of the sheet is inferior or the compatibility with other components is deteriorated, which hinders uniform sheet formation.

As such a binder polymer, acrylic polymer, polyester resin, urethane resin, acrylic urethane resin, silicone resin, phenoxy resin, rubber-based polymer, and the like are used, and acrylic polymer is particularly preferably used.

The glass transition temperature (Tg) of the acrylic polymer is preferably within −60 to 50° C., more preferably −50 to 40° C. In the case where the glass transition temperature of the acrylic polymer is too low, peeling force between the protective layer 20 and the support sheet S2 becomes large, so that transfer failure of the protective layer 20 to the semiconductor substrate 11 occurs or the storage stability in the sheet shape is inferior in some cases. Meanwhile, in the case where the glass transition temperature of the acrylic polymer is too high, the adhesiveness of the protective layer 20 is reduced, so that the protective layer 20 cannot be transferred to the semiconductor substrate 11 or is peeled off from the semiconductor substrate 11 after the transfer in some cases.

Examples of the acrylic polymer include a (meth) acrylic acid ester formed of a (meth) acrylic acid ester monomer and a constituent unit derived from a (meth) acrylic acid derivative. Note that as the (meth) acrylic acid ester monomer, a (meth) acrylic acid alkyl ester having a C1 to C18 alkyl group, e.g., methyl (meth) acrylate, ethyl (meth) acrylate, propyl (meth) acrylate, and butyl (meth) acrylate, is preferably used. Further, examples of the (meth) acrylic acid derivative include a (meth) acrylic acid, a glycidyl (meth) acrylate, and a hydroxyethyl (meth) acrylate.

By copolymerizing glycidyl methacrylate or the like to introduce a glycidyl group into the acrylic polymer, the compatibility with the epoxy resin as a thermosetting adhesive component is improved, Tg after curing is increased, and the heat resistance is also improved. Further, by introducing a hydroxyl group into the acrylic polymer with hydroxyethyl acrylate or the like, it become easy to control the adhesion to the chip and the stickiness.

The protective layer 20 may contain an additive as long as the effect of the present invention is not impaired. The additive may be known one, can be arbitrarily selected according to the purpose, and is not particularly limited. However, favorable examples of the additive include a plasticizer, an antistatic agent, an antioxidant, a colorant (dye, pigment), and a gettering agent.

### Inorganic Filler

The protective layer 20 may further contain a thermally conductive inorganic filler for improving the thermal diffusivity of the protective layer 20.

By blending such an inorganic filler, it is possible to effectively diffuse the heat generation of the semiconductor substrate 11. Further, it is possible to adjust the coefficient of thermal expansion in the protective layer 20 after curing, and improve the reliability of the semiconductor apparatus 100 by optimizing the coefficient of thermal expansion of the protective layer 20 after curing with respect to the semiconductor substrate 11. Further, it is possible to reduce the moisture absorption rate of the protective layer 20 after curing, and maintain the adhesiveness as the protective layer 20 during heating to improve the reliability of the semiconductor apparatus 100. Note that the thermal diffusivity is a value obtained by dividing the thermal conductivity of the protective layer 20 by the product of the specific heat and the specific gravity of the protective layer 20, and it is shown that the larger the thermal diffusivity, the better the heat dissipation characteristic.

Specific examples of the inorganic filler include particles of silica, zinc oxide, magnesium oxide, alumina, titanium, silicon carbide, boron nitride, and the like, beads obtained by making these spherical, single crystal fiber, and glass fiber.

The inorganic filler preferably contains anisotropically shaped particles. The anisotropically shaped particles exhibit a favorable thermal diffusivity in the long axis direction thereof. Therefore, the proportion of anisotropically shaped particles having the long axis direction substantially the same as the thickness direction of the protective layer 20 is increased in the protective layer 20, so that the heat generated in the semiconductor substrate 11 is likely to diverge via the protective layer 20.

Note that the phrase “the long axis direction of anisotropically shaped particles is substantially the same as the thickness direction of the protective layer 20” specifically represents that the long axis direction of anisotropically shaped particles is inclined with respect to the thickness direction (Z axis direction in FIG. 2) of the protective layer 20 within the range of −45° to 45°.

In order to make the long axis direction of anisotropically shaped particles substantially the same as the thickness direction of the protective layer 20, the protective layer 20 may further contain interfering particles. By using the anisotropically shaped particles and the interfering particles in combination, in the step of producing the protective layer 20, it is possible to prevent the long axis direction of anisotropically shaped particles from being substantially the same as the width direction or flow direction of the protective layer 20 to increase the proportion of anisotropically shaped particles having the long axis direction substantially the same as the thickness direction of the protective layer 20. As a result, the protective layer 20 having an excellent thermal diffusivity can be obtained.

Examples of the specific shape of the anisotropically shaped particles include a plate shape, a needle shape, and a scaly shape. Preferable examples of the anisotropically shaped particles include nitride particles. Examples of the nitride particles include particles of boron nitride, aluminum nitride, and silicon nitride. Among them, boron nitride particles that can easily achieve favorable thermal conductivity are preferable.

The average particle size of the anisotropically shaped particles is, for example, not more than 20 μm, preferably 5 to 20 μm. Further, the average particle size of the anisotropically shaped particles is preferably smaller than that of the above-mentioned interfering particles. By adjusting the average particle size of the anisotropically shaped particles as described above, the thermal diffusivity and film formability of the protective layer 20 are improved, and the filling rate of the anisotropically shaped particles in the protective layer 20 is improved.

Meanwhile, the shape of the interfering particles is not particularly limited as long as it prevents the long axis direction of the anisotropically shaped particles from being substantially the same as the width direction or flow direction of the protective layer 20 (direction parallel to the protective layer 20). The specific shape of the interfering particles is, for example, a spherical shape or a flat shape. Examples of the interfering particles include silica particles and alumina particles.

The average particle size of the interfering particles is, for example, more than 20 μm, preferably more than 20 μm and not more than 50 μm, more preferably more than 20 μm and not more than 30 μm. By setting the average particle size of the interfering particles to the above-mentioned range, the thermal diffusivity or film formability of the protective layer 20 is improved. Further, since the anisotropically shaped particles have a large specific surface area per unit volume, it is easy to increase the viscosity of the composition forming the protective layer 20. In the case of adding a filler having a large specific surface area and an average particle size of not more than 20 μm other than anisotropically shaped particles thereto, the viscosity of the composition forming the protective layer 20 is further increased, which may make it difficult to form the protective layer 20, or reduce the productivity due to the necessity of dilution with a larger amount of solvent.

As the interfering particles, the above-mentioned soft magnetic particles may be used. Accordingly, it becomes unnecessary to separately add interfering particles in addition to the soft magnetic particles and the anisotropically shaped particles, so that the filling rate of the soft magnetic particles is improved, which further improves the electromagnetic wave absorption characteristic. In this case, the type of the soft magnetic particles is not limited to one, and may be two or more. For example, in addition to first soft magnetic particles adjusted mainly for electromagnetic wave absorption, second soft magnetic particles having an optimized average particle size may be contained as interfering particles in the protective layer 20.

Incidentally, the protective layer 20 may be colored. The coloring of the protective layer 20 is performed by, for example, blending a pigment, a dye, or the like. By coloring the protective layer 20, the appearance can be improved, and the visibility and discrimination can be enhanced when laser printing is performed. The color of the protective layer 20 is not particularly limited, and may be an achromatic color or a chromatic color. In this embodiment, the protective layer 20 is colored black.

Note that a coupling agent may be added to the protective layer 20 for the purpose of improving the adhesiveness/adhesion between the protective layer 20 after curing and the back surface of the semiconductor substrate 11. The coupling agent can improve not only the adhesiveness and adhesion without impairing the heat resistance of the protective layer 20, and also the water resistance (moisture and heat resistance) is improved.

### Peeling Sheet

The peeling sheet S1 is provided so as to cover the adhesive surface 201 of the protective layer 20, and peeled off from the adhesive surface 201 when the protective layer 20 is used.

As the peeling sheet S1, for example, a polyethylene film, a polypropylene film, a polybutene film, a polybutadiene film, a polymethylpentene film, a polyvinyl chloride film, a vinyl chloride copolymer film, a polyethylene terephthalate film, polyethylene naphthalate film, a polybutylene terephthalate film, a polyurethane film, an ethylene vinyl acetate film, an ionomer resin film, an ethylene-(meth) acrylic acid copolymer film, an ethylene-(meth) acrylic ester copolymer film, a polystyrene film, a polycarbonate film, a polyimide film, a fluorine resin film, and the like are used. Further, crosslinked films thereof are also used. Further, laminated films thereof may be used.

As the peeling sheet S1, a film obtained by applying a release treatment to one surface of the above-mentioned film is preferable. As a release agent used for the peeling treatment is not particularly limited, but silicone-based, fluorine-based, alkyd-based, unsaturated polyester-based, polyolefin-based, and wax-based release agent are used, for example. In particular, the silicone-based release agent is preferable because a low peeling force can be easily achieved. It does not need to perform the release treatment in the case where the film used as the peeling film has a low surface tension of its own and exhibits a low peeling force with respect to the adhesive layer like the polyolefin film.

Further, the surface tension of the peeling sheet S1 is preferably not more than 40 mN/m, more preferably not more than 37 mN/m, particularly preferably not more than 35 mN/m. Such a peeling sheet S1 having a low surface tension can be obtained by appropriately selecting a material, or by applying silicone resin or the like on the surface of the peeling sheet S1 to perform a release treatment.

The thickness of the peeling sheet S1 is usually approximately 5 to 300 μm, preferably 10 to 200 μm, particularly preferably 20 to 150 μm.

### Support Sheet

The support sheet S2 is peelably stuck to the front surface 202 opposite to the adhesive surface 201 of the protective layer 20, and plays a role as a supporting body when the protective layer 20 is stuck to the semiconductor substrate 11.

The support sheet S2 includes a base material film based on a resin-based material. Specific examples of the base material film include a polyolefin film such as a polyethylene film such as a low-density polyethylene (LDPE) film, a linear low-density polyethylene (LLDPE) film, and a high-density polyethylene (HDPE) film, a polypropylene film, a polybutene film, a polybutadiene film, a polymethylpentene film, an ethylene-norbornene copolymer film, and a norbornene resin film; an ethylene-based copolymer film such as an ethylene-vinyl acetate copolymer film, an ethylene-(meth) acrylic acid copolymer film, and an ethylene-(meth) acrylic ester copolymer film; a polyvinyl chloride-based film such as a polyvinyl chloride film and a vinyl chloride copolymer film; a polyester-based film such as a polyethylene terephthalate film and a polybutylene terephthalate film; a polyurethane film; a polyimide film; a polystyrene film; a polycarbonate film; and a fluorine resin film. Further, modified films such as crosslinked films and ionomer films of these films can also be used. The base layer may be a film including one of these, or a laminated film obtained by combining two or more of these.

Alternatively, as the base material film constituting the support sheet S2, a resin film constituting the above-mentioned peeling sheet S1 may be used. Further, as the support sheet S2, a film obtained by applying adhesion processing to the above-mentioned base material film may be used. Further, the support sheet S2 may be replaced with a dicing sheet after curing the protective layer 20.

The thickness of the support sheet S2 is not particularly limited, and is, for example, within the range of not less than 10 μm and not more than 500 μm, preferably not less than 15 μm and not more than 300 μm, particularly preferably not less than 20 μm and not more than 250 μm.

### Method of Producing Semiconductor Apparatus

Next, a method of producing the semiconductor apparatus 100 will be described.

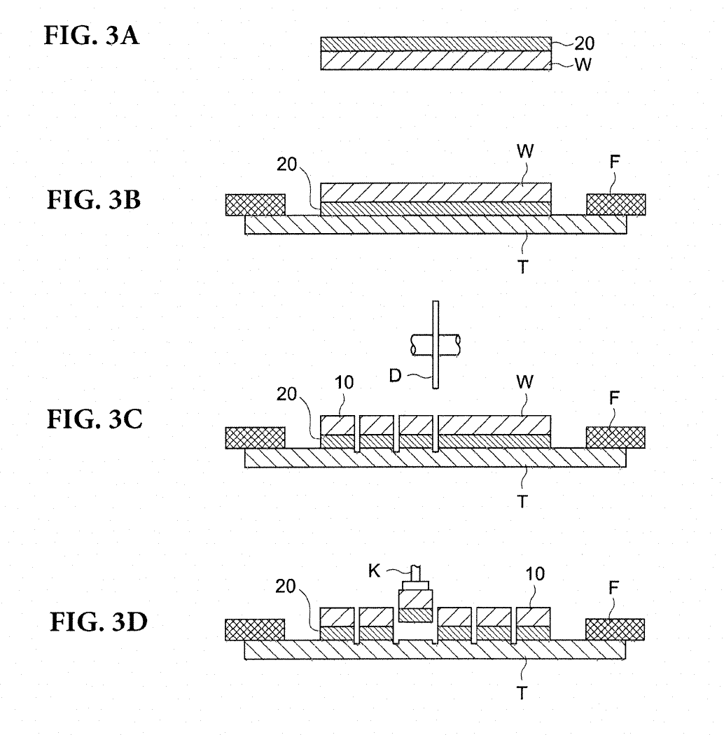

Part A to Part D of FIG. 3 are each a schematic process cross-sectional view describing a method of producing the semiconductor apparatus 100.

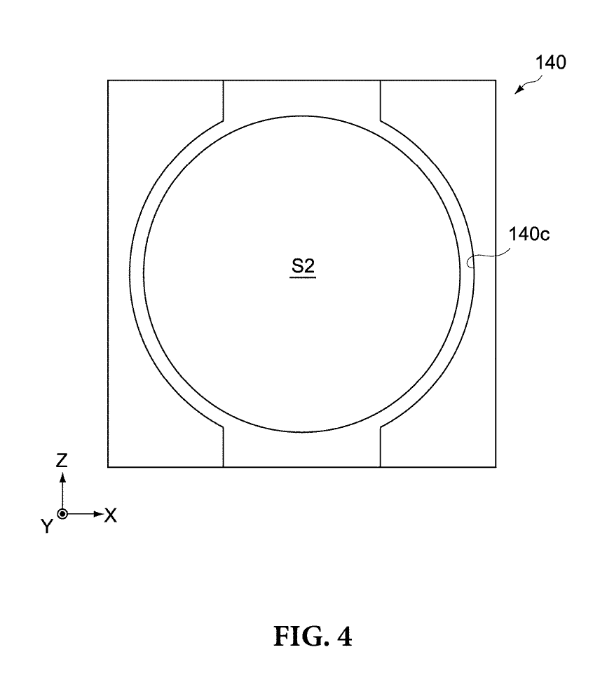

First, as shown in Part A of FIG. 3, the protective layer 20 is stuck to the back surface of a semiconductor wafer W. Note that in the sticking step of the protective layer 20, for example, the pre-cut composite sheet 140 (401, 402) to be described later may be used (FIG. 4 to FIG. 6).

The semiconductor wafer W is thinned to a predetermined thickness (e.g., 50 μm) in advance by a back grinding step. Further, on the surface (circuit surface) of the semiconductor substrate W, the wiring layer 12 and the plurality of bumps 13 are formed at the wafer level.

The protective layer 20 is formed in, for example, substantially the same size and shape as the semiconductor wafer W, and is in a state before curing treatment. The peeling sheet S1 is peeled off from the adhesive surface 201 before being stuck to the semiconductor wafer W. Further, the protective layer 20 is stuck to the back surface of the semiconductor wafer W via the adhesive surface 201. Then, the support sheet S2 is peeled off from the front surface 202 of the protective layer 20, thereby obtaining a laminated body of the semiconductor wafer W and the protective layer 20. Next, the protective layer 20 is cured. As a result, a single composite material layer formed of the cured product of the protective layer 20 is formed on the entire surface of the semiconductor wafer W.

By sticking the protective layer 20 before curing to the semiconductor wafer W, the apparent thickness of the semiconductor wafer W is increased. As a result, the rigidity of the semiconductor wafer W is enhanced, and the handling property and dicing suitability are improved. Accordingly, it is possible to effectively protect the semiconductor wafer W from damage, cracks, and the like.

Next, a printing layer for displaying product information is formed on the cured product of the protective layer 20. The printing layer is formed by applying an infrared laser (laser marking) to the front surface of the protective layer 20. The printing layer includes characters, signs, or graphics for displaying the type or the like of the semiconductor chip or semiconductor apparatus. By forming the printing layer at the wafer level, it is possible to efficiently print predetermined product information on individual chip areas.

Next, as shown in Part B of FIG. 3, the semiconductor wafer W to which the protective layer 20 is adhered is mounted on the adhesive surface of a dicing sheet T. The dicing sheet T protects and fixes the semiconductor substrate in the step of dicing the semiconductor substrate, and picks up the semiconductor chips divided into chips having a chip size. The dicing sheet T is placed on a dicing table (not shown) with the adhesive layer provided on one side thereof facing upward, and is fixed by a ring frame F. The semiconductor wafer W is fixed on the dicing sheet T via the protective layer 20 with the circuit surface thereof facing upward.

Then, as shown in Part C of FIG. 3, the semiconductor wafer W is diced for each circuit (in units of chips) by a dicer D. At this time, the blade of the dicer D cuts the semiconductor wafer W to a depth reaching the upper surface (adhesive surface) of the dicing sheet T. Therefore, the protective layer 20 is cut in units of chips along with the semiconductor wafer W.

Next, as shown in Part D of FIG. 3, by a collet K, the chip-like semiconductor device 10 and the protective layer 20 are separated from the adhesive layer of the dicing sheet T. Accordingly, the semiconductor apparatus 100 in which the protective layer 20 is provided on the back surface of the semiconductor device 10 is produced.

FIG. 4 is a schematic plan view showing a pre-cut shape of the composite sheet 140. The composite sheet 140 typically includes a strip-shaped sheet, and a punching groove 140c having substantially the same size as the semiconductor wafer is provided in a state where the support sheet and the protective layer are removed in each layer excluding the peeling sheet S1. That is, in the illustrated example, the protective layer 20 and the support sheet S2 are supported by the peeling sheet S1 in the state of being pre-cut to a size equal to or larger than that of the semiconductor wafer, and are to be adhered in the substrate size to the back surface of the semiconductor wafer W.

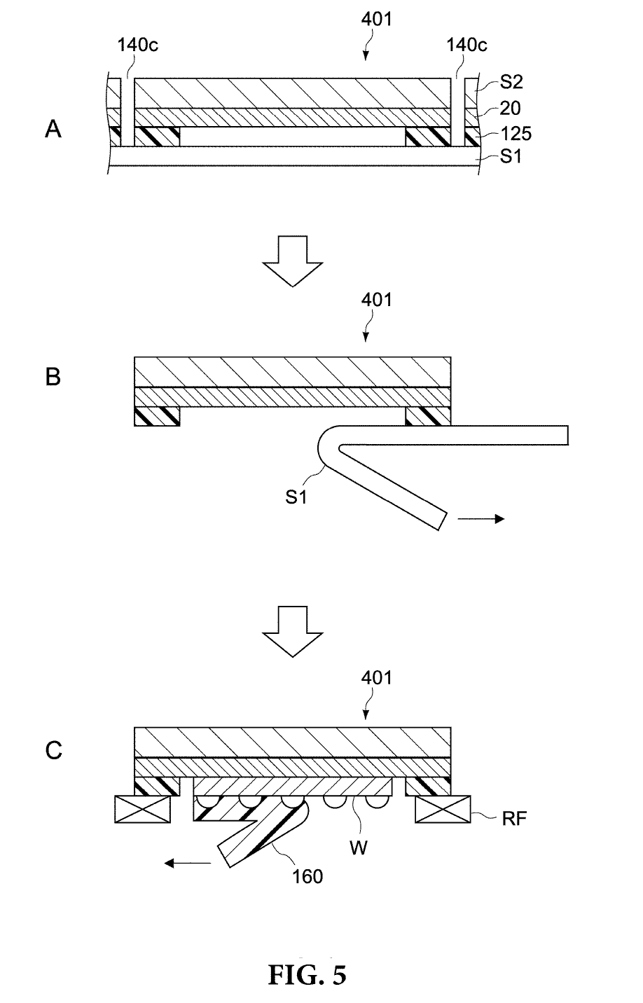

Part A to Part C of FIG. 5 are each a schematic cross-sectional view describing an example of a step of adhering the protective layer 20 to the back surface of the semiconductor wafer W. As shown in the figure, after peeling off the peeling sheet S1, a composite sheet 401 is bonded to the back surface of the semiconductor wafer W (upper surface in Part C of FIG. 5), and curing treatment of the protective layer 20 is performed. In the illustrated composite sheet 401, an annular pressure-sensitive adhesive layer 125 to be adhered to a ring frame RF is laminated in advance on the peripheral portion of the protective layer 20 pre-cut to a size larger than the semiconductor wafer size, and the semiconductor wafer W is adhered to the inside of the adhesive layer area partitioned by the pressure-sensitive adhesive layer 125. A protective member 160 laminated on the front surface (lower surface in Part C of FIG. 5) of the semiconductor wafer W is removed before performing curing treatment on the protective layer 20.

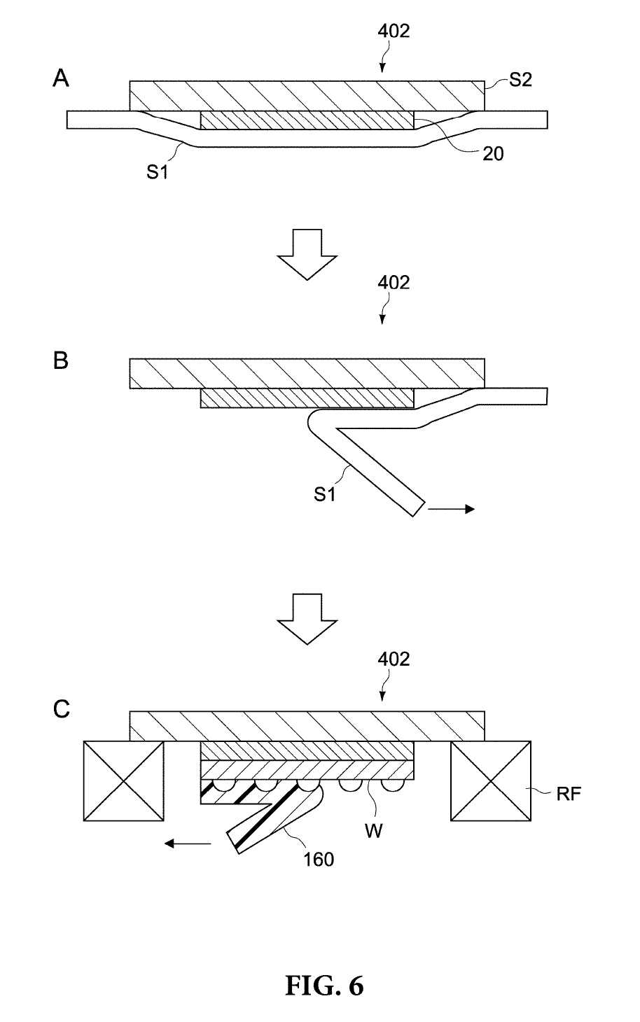

Meanwhile, a composite sheet 402 shown in Part A of FIG. 6 includes the protective layer 20 pre-cut to a size equal to the semiconductor wafer size and the support sheet S2 pre-cut to a size larger than the semiconductor wafer size, and the peeling sheet S1 is adhered to the support sheet S2 so as to cover the protective layer 20. Then, as shown in Part B and Part C of FIG. 6, after peeling off the peeling sheet S1, the composite sheet 402 is bonded to the back surface (upper surface in FIG. 6) of the semiconductor wafer W, and curing treatment of the protective layer 20 is performed. The support sheet S2 is adhesively supported by the ring frame RF via a pressure-sensitive adhesive layer (not shown). The protective member 160 laminated on the front surface (lower surface in Part C of FIG. 6) of the semiconductor wafer W is removed before performing curing treatment of the protective layer 20.

As the composite sheet 140, the composite sheet 401 shown in Part A of FIG. 5 may be adopted, or the composite sheet 402 shown in Part A of FIG. 6 may be adopted. Further, the support sheet S2 in the composite sheet 401 or 402 may include a dicing sheet, as described above.

In the semiconductor apparatus 100 according to this embodiment, the protective layer 20 is integrated with the semiconductor substrate 11 by bonding the adhesive surface 201 to the back surface of the semiconductor substrate 11. Therefore, since the protective layer 20 that protects the back surface of the semiconductor substrate 11 includes a single layer, the thicknesses of the protective layer 20 and the semiconductor apparatus 100 can be reduced.

Further, since the protective layer 20 is formed of a composite material containing soft magnetic particles, the bending strength of the semiconductor substrate 11 can be enhanced, and electromagnetic noise emitted from the semiconductor substrate 11 to the outside and electromagnetic noise entering the semiconductor substrate 11 from the outside can be suppressed.

The present inventors prepared a protective layer having a thickness of 300 μm in which 60% by mass of soft magnetic particles (Sendust, manufactured by Sanyo Special Steel Co., Ltd., trade name “FME3DH”) were dispersed, as the protective layer 20, adhered the sheet on a microstrip line in accordance with international standard IEC62333, and measured a transmission coefficient S21 and a reflection coefficient S11 at this time with a network analyzer. From these measured values, Rtp (transmission attenuation rate) was calculated using the equation Rtp=−10 log₁₀{10^{S21/10}/(1-10^{S11/10})}.

As a result, the value of Rtp was 24.4 when the measurement frequency was 5 GHz.

Further, according to this embodiment, since the protective layer to be stuck to the back surface of the semiconductor substrate contains soft magnetic particles, it is possible to produce a semiconductor apparatus having an electromagnetic wave absorption function in a step similar to the step of producing a semiconductor apparatus including a protective layer that does not contain soft magnetic particles. Therefore, it is possible to reduce the number of steps as compared with the case where an electromagnetic wave absorbing sheet is additionally placed on the wiring substrate on which the semiconductor apparatus is mounted. Further, since space for separately placing the electromagnetic wave absorbing sheet on the wiring substrate is unnecessary, high-density mounting of parts becomes possible, which makes it possible to contribute to miniaturization and thinning of an electronic apparatus.

### Second Embodiment

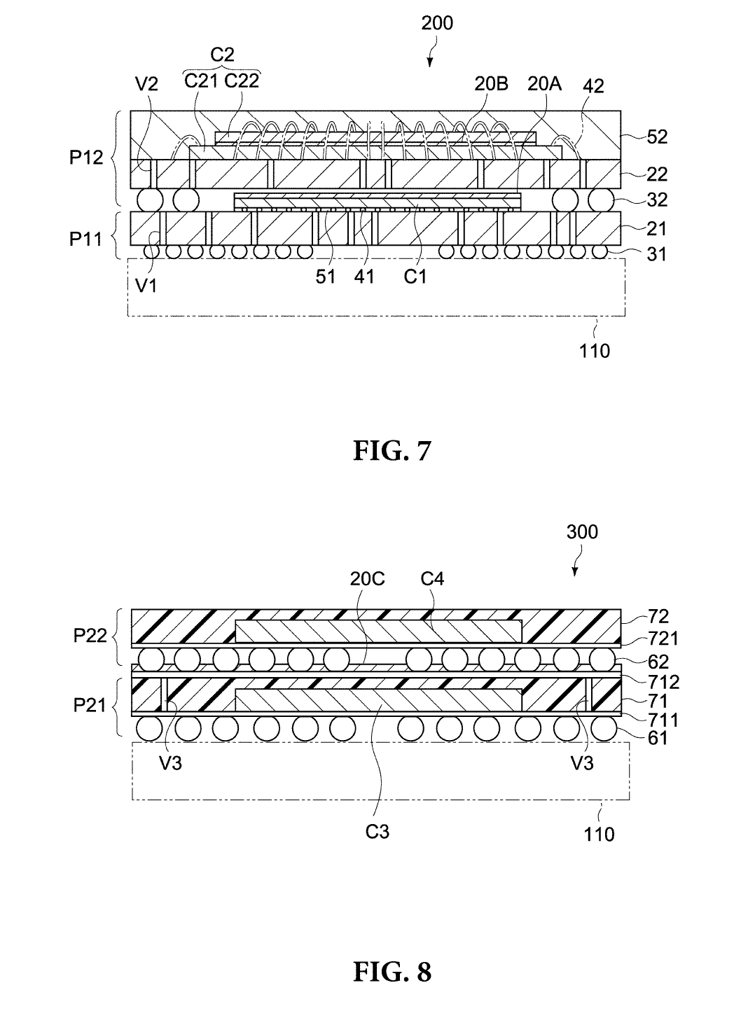

FIG. 7 is a schematic cross-sectional side view showing a configuration of a semiconductor apparatus 200 according to a second embodiment of the present invention.

As shown in FIG. 7, the semiconductor apparatus 200 according to this embodiment has a laminated structure (PoP:Package on Package) of a first semiconductor package P11 and a second semiconductor package P12.

The first semiconductor package P11 includes a first wiring substrate 21 and a first semiconductor chip C1 flip-chip mounted (flip-chip connected) on the first wiring substrate 21.

The second semiconductor package P12 is mounted on the first semiconductor package P11. The second semiconductor package P12 includes a second wiring substrate 22 and a second semiconductor chip C2 wire-bonded on the second wiring substrate 22. The second semiconductor chip C2 has a laminated structure of two semiconductor chips C21 and C22 having different sizes.

Typically, the first semiconductor chip C1 and the second semiconductor chip C2 (C21, C22) each include a bare chip including a single crystal silicon (Si) substrate or a semiconductor device such as a CSP. On the surface thereof, a circuit surface in which a plurality of circuit devices such as a transistor and a memory are integrated is formed.

The first semiconductor chip C1 is mounted on the upper surface of the first wiring substrate 21 in a face-down method with the circuit surface thereof facing the first wiring substrate 21. The first semiconductor chip C1 is electrically and mechanically connected to the first wiring substrate 21 via a plurality of bumps (bump electrodes) 41 formed on the circuit surface (lower surface in the figure). For bonding the first semiconductor chip C1 to the first wiring substrate 21, for example, a reflow soldering method using a reflow furnace is adopted.

Between the first semiconductor chip C1 and the first wiring substrate 21, typically, an underfill resin layer 51 is provided. The underfill resin layer 51 is provided in order to improve the connection reliability of the bumps 41 by sealing the circuit surface and the bumps 41 of the first semiconductor chip C1 and blocking the outside air to increase the bonding strength between the first semiconductor chip C1 and the first wiring substrate 21.

To the back surface (surface opposite to the circuit surface, upper surface in the figure) of the first semiconductor chip C1, a protective layer 20A for protecting the semiconductor chip C1 is bonded. Similarly to the protective layer 20 in the above-mentioned first embodiment, the protective layer 20A is formed of a single layer of a composite material containing soft magnetic particles, and has a function of increasing the bending strength of the first semiconductor chip C1 and suppressing electromagnetic noise emitted from the first semiconductor chip C1 and electromagnetic noise entering the first semiconductor chip C1.

Meanwhile, the second semiconductor chip C2 (C21, C22) is mounted on the upper surface of the second wiring substrate 22 in a face-up method with the back surface opposite to the circuit surface thereof facing the second wiring substrate 22. The second semiconductor chip C2 (C21, C22) includes a plurality of electrode pads (illustration omitted) arranged around the circuit surfaces (upper surface in the figure), and is connected to the second wiring substrate 22 via a plurality of bonding wires 42 connected to the electrode pads

The second wiring substrate 22 and the semiconductor chip C21 are bonded to each other via a nonconductive adhesive (illustration omitted). Meanwhile, the two semiconductor chips C21 and C22 are bonded to each other via a protective layer 20B. Similarly to the protective layer 20 in the above-mentioned first embodiment, the protective layer 20B is formed of a single layer of a composite material containing soft magnetic particles, and has a function of suppressing electromagnetic cross talk between the two semiconductor chips C21 and C22.

On the upper surface of the second wiring substrate 22, a sealing layer 52 for sealing the second semiconductor chip C2 (C21, C22) and the bonding wires 42 is provided. Similarly to the underfill resin layer 51, the sealing layer 52 is provided in order to improve the connection reliability of the second semiconductor chip C2 (C21, C22) and the second wiring substrate 22 by shielding the circuit surface of the second semiconductor chip C2 (C21, C22) to block the outside air.

The first wiring substrate 21 and the second wiring substrate 22 may be formed of the same kind of materials or different materials. Typically, the first wiring substrate 21 and the second wiring substrate 22 each include an organic wiring substrate such as a glass epoxy substrate and a polyimide substrate. Alternatively, a ceramic substrate or a metal substrate may be used. The type of the wiring substrate is not particularly limited, and various substrates such as a single-sided substrate, a double-sided substrate, a multilayer substrate, and a device built-in substrate can be applied. In this embodiment, the first and second wiring substrates 21 and 22 include glass epoxy-based multilayer wiring substrates having vias V1 and V2, respectively.

On the back surface (lower surface in the figure) of the first wiring substrate 21, a plurality of external connection terminals 31 to be connected to a control board 110 called a mother board or the like are provided. The first wiring substrate 21 is configured as an interposer substrate (daughter substrate) interposed between the first semiconductor chip C1 and the control board 110, and also has a function as a re-wiring layer for converting the arrangement interval of the bumps 51 on the circuit surface of the first semiconductor chip C1 into the land pitch of the control board 110.

On the back surface (lower surface in the figure) of the second wiring substrate 22, a plurality of bumps 32 to be connected to the front surface of the first wiring substrate 21 are provided. The second wiring substrate 22 is configured as an interposer substrate that connects the second semiconductor chip C2 (C21, C22) to the first wiring substrate, and is electrically connected to the control board 110 via the first wiring substrate 21 and the external connection terminals 31.

Typically, the external connection terminals 31 and the bumps 41 and 32 each include a solder bump (ball bump). Alternatively, they may include another bump electrode such as a plating bump and a stud bump. For connecting the second wiring substrate 22 to the first wiring substrate 21 and connecting the semiconductor apparatus 100 to the control board 110, a reflow soldering method is adopted.

In the semiconductor apparatus 200 according to this embodiment configured as described above, the protective layer 20A and the protective layer 20B are respectively provided on the back surface of the semiconductor chip C1 and between the semiconductor chip C21 and the semiconductor chip C22. Since the protective layers 20A and 20B having an electromagnetic wave absorption function are provided between the semiconductor chips C1, C21, and C22 in the lamination direction of the semiconductor packages P11 and P12 as described above, it is possible to suppress electromagnetic cross talk between these semiconductor chips and ensure predetermined electrical characteristics, thereby improving the reliability of the semiconductor apparatus 200. Further, since each of the protective layers 20A and 20B includes a single layer, it is possible to promote the thinning of the semiconductor apparatus 200 having a PoP structure.

### Third Embodiment

FIG. 8 is a schematic cross-sectional side view showing a configuration of a semiconductor apparatus 300 according to a third embodiment of the present invention.

As shown in FIG. 8, the semiconductor apparatus 300 according to this embodiment has a laminated structure (PoP:Package on Package) of a first semiconductor package P21 and a second semiconductor package P22. The first semiconductor package P21 and the second semiconductor package P22 are each configured with a fan-out type wafer level package (Fan-Out WLP).

The semiconductor packages P21 and P22 respectively include semiconductor chips C3 and C4, package bodies 71 and 72 formed to have sizes larger than those of the semiconductor chips C3 and C4, wiring layers 711 and 721 provided on the lower surface of the package bodies 71 and 72, a plurality of bumps 61 and 62 fixed to the wiring layers 711 and 721, and the like.

The semiconductor chips C3 and C4 are respectively incorporated into the package bodies 71 and 72 with the respective circuit surfaces facing downward, and electrically connected to the wiring layers 711 and 721. Since the package bodies 71 and 72 are respectively formed to have sizes larger than those of the semiconductor chips C3 and C4, the electrode pitch of /the semiconductor chips C3 and C4 can be significantly expanded in the wiring layers 711 and 721, which increases the degree of freedom of arrangement of the bumps 61 and 62.

The bumps 61 of the first semiconductor package P21 are for connecting the first semiconductor package P21 (semiconductor apparatus 300) to the control board 110. Meanwhile, the bumps 62 of the second semiconductor package P22 are connected to a wiring layer 712 provided on the upper surface of the first semiconductor package P21, and electrically connected to the wiring layer 711 and the bumps 61 via vias V3 provided on the package body 71.

The semiconductor apparatus 300 further includes a protective layer 20C. The protective layer 20C is provided on the back surface (upper surface of the wiring layer 712 in this example) of the first semiconductor package P21. The protective layer 20C includes a single layer of a composite material containing soft magnetic particles, similarly to the protective layer 20 according to the first embodiment. The protective layer 20C is bonded to the upper surface (wiring layer 712) of the package body 71 via the adhesive surface 201 (see FIG. 2), and has openings for connecting the bumps 62 to the wiring layer 712.

After being stuck in a semi-cured state to the wiring layer 712, curing treatment is performed to cure the protective layer 20C. The curing treatment may be performed before the second semiconductor package P22 is laminated or after the second semiconductor package P22 is laminated.

In the semiconductor apparatus 300 according to this embodiment, the protective layer 20C has a function of increasing the bending strength of the first semiconductor package P21, and suppressing electromagnetic noise emitted from the semiconductor chip C3 and electromagnetic noise entering the semiconductor chip C3. Further, the protective layer 20C has also a function of suppressing electromagnetic cross talk between the two semiconductor packages P21 and P22. Further, the protective layer 20C has also a function as a nonconductive adhesive film (NCF:Non-Conductive Film) for increasing the bonding strength between the first semiconductor package P21 and the second semiconductor package P22.

### Fourth Embodiment

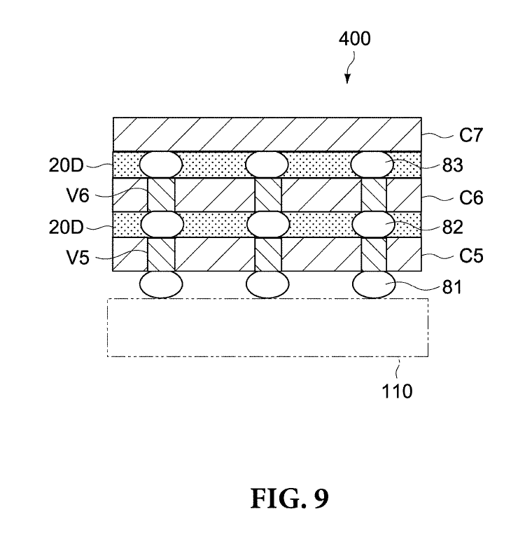

FIG. 9 is a schematic cross-sectional side view showing a configuration of a semiconductor apparatus 400 according to a fourth embodiment of the present invention.

As shown in FIG. 9, the semiconductor apparatus 400 according to this embodiment has a laminated structure (CoC:Chip on Chip) of a plurality of semiconductor chips C5, C6, and C7.

The semiconductor chips C5 to C7 are laminated with the respective circuit surfaces facing downward. That is, the semiconductor chip C6 at the middle stage is laminated on the back surface of the semiconductor chip C5 at the lowermost stage, and the semiconductor chip C7 at the uppermost stage is laminated on the back surface of the semiconductor chip C6 at the middle stage.

In the semiconductor chip C5 at the lowermost stage and the semiconductor chip C6 at the middle stage, a plurality of vias (TSV:Through-Silicon Via) V5 and V6 penetrating therethrough in the thickness direction thereof are provided, respectively. The vias V5 and V6 opposed to each other in the lamination direction so as to be aligned with each other. Between these vias V5 and V6, bumps 82 for electrically connecting the semiconductor chip C5 and the semiconductor chip C6 are arranged. Further, at the lower end of the vias V5, bumps 81 for connecting the semiconductor chip C5 (semiconductor apparatus 400) to the control board 110 are arranged. At the upper end of the vias V6, bumps 83 for connecting the semiconductor chip C7 at the uppermost stage to the semiconductor chip C6 are arranged.

The semiconductor apparatus 400 further includes a plurality of adhesive layers 20D that bond the semiconductor chip C5 and the semiconductor chip C6 to each other and bond the semiconductor chip C6 and the semiconductor chip C7 to each other. The adhesive layers 20D each include a single layer of a composite material containing soft magnetic particles, similarly to the protective layer 20 according to the first embodiment. The shape of each of the adhesive layers 20D is not limited to a sheet shape or film shape, and may be a paste shape.

After being stuck in a semi-cured state to the semiconductor chips C5 and C6, curing treatment is performed to cure each of the adhesive layers 20D. The curing treatment may be performed for each of the adhesive layers 20D, or simultaneously performed for all the adhesive layers 20D.

In the semiconductor apparatus 400 according to this embodiment, the adhesive layers 20D have a function of increasing the bending strength of the semiconductor chips C5 to C7, and suppressing electromagnetic noise emitted from the semiconductor chips C5 to C7 and electromagnetic noise entering the semiconductor chips C5 to C7. Further, the adhesive layers 20D have also a function of suppressing electromagnetic cross talk between the semiconductor chips C5 to C7. Further, the adhesive layers 20D have also a function as a nonconductive adhesive film (NCF:Non-Conductive Film) for increasing the bonding strength between the semiconductor chips C5 to C7.

Although embodiments of the present invention have been described, it goes without saying that the present invention is not limited to the above-mentioned embodiments and various modifications can be made.

For example, in the above-mentioned embodiments, WLCSP, PoP, and CoC have been described as examples of semiconductor apparatuses. However, it goes without saying that the present invention is not limited thereto. For example, the present invention is applicable also to a device built-in substrate in which a semiconductor device is embedded in a wiring substrate, and the like. In this case, the protective layer according to the present invention is provided on the back surface of the semiconductor device to be embedded. Accordingly, it is possible to suppress electromagnetic cross talk between the semiconductor device and various electric parts mounted on the device built-in substrate.

Further, in the above-mentioned fourth embodiment, to the back surface (upper surface) of the semiconductor chip C7 at the uppermost stage, the protective layer 20 described in the first embodiment may be bonded. Accordingly, it is possible to protect the back surface of the semiconductor chip C7 and further suppress electromagnetic noise emitted from the semiconductor chip C7 and electromagnetic noise entering the semiconductor chip C7.

### DESCRIPTION OF SYMBOLS

10 semiconductor device
11 semiconductor substrate
20, 20A, 20B, 20C protective layer
20D adhesive layer
100, 200, 300, 400 semiconductor apparatus
140, 401, 402 composite sheet
201 adhesive surface
C1 to C7 semiconductor chip
P11, P12, P21, P22 semiconductor package

1. A semiconductor apparatus, comprising:
a semiconductor substrate that has a first surface constituting a circuit surface, and a second surface opposite to the first surface; and
a protective layer that includes a single layer of a composite material containing soft magnetic particles, and has an adhesive surface to be adhered to the second surface.

2. The semiconductor apparatus according to claim 1, wherein
the composite material is formed of a cured product of adhesive resin containing the soft magnetic particles.

3. The semiconductor apparatus according to claim 1, wherein
the protective layer further contains thermally conductive particles.

4. A semiconductor apparatus, comprising:
a wiring substrate;
a semiconductor device that has a first surface constituting a circuit surface and a second surface opposite to the first surface, and is mounted on the wiring substrate; and
a protective layer that includes a single layer of a composite material containing soft magnetic particles, and has an adhesive surface to be adhered to the second surface.

5. The semiconductor apparatus according to claim 4, further comprising
a semiconductor package component to be electrically connected to the wiring substrate, wherein
the semiconductor device is disposed between the wiring substrate and the semiconductor package component.

6. A semiconductor apparatus, comprising:
a first semiconductor device;
a second semiconductor device that is disposed on the first semiconductor device, and electrically connected to the first semiconductor device; and
an adhesive layer that is formed of a nonconductive composite material containing soft magnetic particles, and disposed between the first semiconductor device and the second semiconductor device.

7. A composite sheet bonded to a second surface opposite to a first surface constituting a circuit surface of a semiconductor substrate, the composite sheet comprising:
a protective layer that includes a single layer of a composite material containing soft magnetic particles, and has an adhesive surface to be adhered to the second surface; and
a support sheet that is peelably stuck to a front surface of the protective layer opposite to the adhesive surface.

8. The composite sheet according to claim 7, wherein
the support sheet includes a dicing sheet.

9. The composite sheet according to claim 7, wherein
the protective layer further contains a thermally conductive inorganic filler.

10. The composite sheet according to claim 9, wherein
the inorganic filler contains anisotropically shaped particles having substantially the same long axis direction as a thickness direction of the protective layer.

11. The semiconductor apparatus according to claim 2, wherein
the protective layer further contains thermally conductive particles.

12. The composite sheet according to claim 8, wherein
the protective layer further contains a thermally conductive inorganic filler.

13. The composite sheet according to claim 12, wherein
the inorganic filler contains anisotropically shaped particles having substantially the same long axis direction as a thickness direction of the protective layer.
